(19) United States
(12) Patent Application Publication
(10) Pub. No.: US 2008/0157246 A1
(43) Pub. Date: Jul. 3, 2008

(54) Image sensor and fabricating method thereof

(75) Inventors: Chang Hun Han, Icheon-si (KR); Joon Hwang, Cheongju-si (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu HiTek Co., Ltd.

(21) Appl. No.: 12/001,638

(22) Filed: Dec. 11, 2007

(30) Foreign Application Priority Data
Dec. 27, 2006 (KR) 10-2006-0134642

(51) Int. Cl. H01L 31/0232; H01L 31/18

(52) U.S. Cl. 257/432; 438/70; 257/E31.127

(57) ABSTRACT

An image sensor may include a color filter layer on a semiconductor substrate; and a microlens on the color filter layer and including a non-photosensitive insulating layer.

The present application claims priority under 35 U.S.C. 119 and 35 U.S.C. 365 to Korean Patent Application No. 10-2006-0134642 (filed on Dec. 27, 2006), which is hereby incorporated by reference in its entirety.

### BACKGROUND

Embodiments of the invention relate to an image sensor and a fabrication method thereof.

The image sensor is a semiconductor device that converts an optical image into an electrical signal. Among the problems to be solved in fabricating the image sensor is to increase a rate of converting incident light signals into electrical signals, that is, sensitivity. Therefore, in forming the microlens array for condensing light, various techniques for implementing a zero gap (i.e., no gap between neighboring lenses in the microlens array) are devised.

When forming the microlens for condensing light using a photosensitive layer, the phenomenon that particles of materials such as polymer, silicon, silicon dioxide, etc., generated in a wafer back grinding process and/or a wafer sawing process and the like may adhere to the microlens. This may degrade the sensitivity of the image sensor as well as the fabrication yield due to the difficulty of cleaning such particles from such a microlens.

### SUMMARY OF THE INVENTION

Embodiments of the invention provide an image sensor and a fabricating method capable of improving sensitivity by effectively transferring incident light to a photodiode area.

An image sensor according to one embodiment of the invention comprises a color filter layer on a semiconductor substrate and a microlens array on the color filter layer comprising a non-photosensitive insulating layer, wherein the microlens array comprises a first microlens on a first color filter and a second microlens on a second color filter, the first microlens and the second microlens having a different thickness from each other.

An image sensor according to another embodiment comprises a color filter layer on a semiconductor substrate and a microlens array on the color filter layer comprising a non-photosensitive insulating layer, wherein the microlens array comprises a first microlens on a first color filter, a second microlens on a second color filter, and a third microlens on a third color filter, wherein each of the first, second, and third microlenses have a different thickness from each other.

A method of fabricating an image sensor according to another embodiment comprises forming a non-photosensitive insulating layer on a color filter layer; forming a photosensitive layer on the non-photosensitive insulating layer; forming a sacrificial microlens by patterning the photosensitive layer; forming a microlens from the non-photosensitive insulating layer by etching the sacrificial microlens and the non-photosensitive insulating layer.

### BRIEF DESCRIPTION OF THE DRAWINGS

FIGS. 1 to 4 are views conceptually showing a method of fabricating an image sensor according to embodiments of the invention; and

FIGS. 5 to 7 are views conceptually showing an alternative method of fabricating an image sensor according to embodiments of the invention.

### DETAILED DESCRIPTION OF THE EMBODIMENTS

In the following description of various embodiments, when each layer (film), an area, a pattern or structures are described to be formed “on/above” or “below/under” each layer (film), the area, the pattern or the structures, it can be understood as the case that each layer (film), an area, a pattern or structures are formed by being directly contacted to each layer (film), the area, the pattern or the structures and it can further be understood as the case that other layer (film), other area, other pattern or other structures are additionally formed therebetween. Therefore, the meanings should be judged according to the technical idea of the embodiment.

Hereinafter, various embodiments will be described with reference to the accompanying drawings.

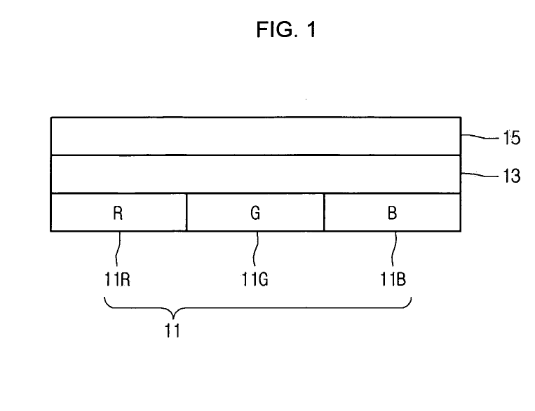

FIGS. 1 to 4 are views conceptually showing an exemplary method of fabricating an image sensor.

With the exemplary method of fabricating an image sensor according to one embodiment, as shown in FIG. 1, a non-photosensitive insulating layer 13 is formed on a color filter layer 11. The color filter layer 11 can comprise or be formed of a red color filter 11R, a green color filter 11G, and a blue color filter 11B. Alternatively, the color filter layer 11 can comprise a yellow color filter, a cyan color filter, and a magenta color filter. In either case, the color filters 11R, 11G, and 11B may have the same thickness or different thicknesses. The arrangement of the red color filter 11R, the green color filter 11G, the blue color filter 11b forming the color filter layer 11 can be varied according to the design.

The non-photosensitive insulating layer 13 can comprise or be formed of a rigid material and/or a transparent material, as compared to the photosensitive material. The non-photosensitive insulating layer 13 can comprise or be formed of a transparent oxide layer (for example, silicon dioxide, aluminum oxide, various silicates, aluminates, aluminosilicates and titanates, zirconium oxide, hafnium oxide, etc.). The photosensitive layer 15 (which generally comprises a photoresist) is formed on the non-photosensitive insulating layer 13.

In the exemplary embodiments, prior to forming the color filter layer 11, the method can further comprise forming a light receiving part in the semiconductor substrate. The light receiving part can comprise a photodiode as one example.

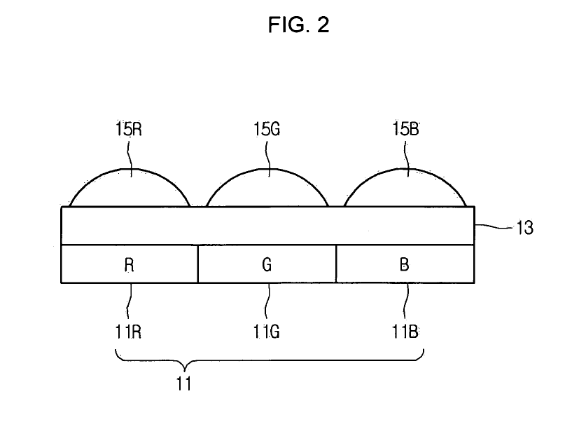

Next, as shown in FIG. 2, the photosensitive layer 15 is patterned through an exposure process and a developing process to form sacrificial microlenses 15R, 15G, and 15B. The sacrificial microlenses 15R, 15G, and 15B can comprise a red sacrificial microlens 15R, a green sacrificial microlens 15G, and a blue sacrificial 15B. The red sacrificial microlens 15R is formed in a position corresponding to the red color filter 11R, the green sacrificial microlens 15G is formed in a position corresponding to the green color filter 11G, and the blue sacrificial microlens 15B is formed in a position corresponding to the blue color filter 11B. All of the red sacrificial microlens 15R, the green sacrificial microlens 15G, and the blue sacrificial microlens 15B can have the same thickness or different thicknesses.

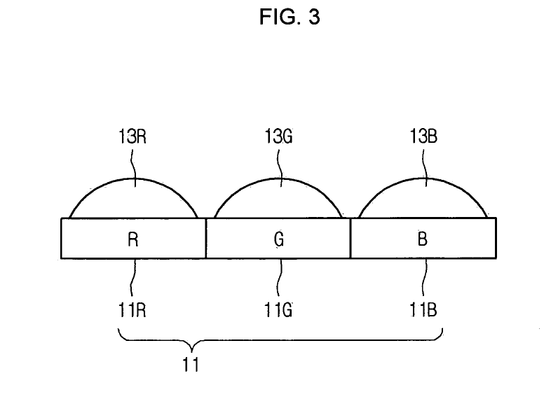

Thereafter, as shown in FIG. 3, the microlenses 13R, 13G, and 13B are formed in the non-photosensitive insulting layer by etching the sacrificial microlenses 15R, 15G, and 15B and the non-sensitive insulating layer 13. At this time, with respect to the etch for the sacrificial microlenses 15R, 15G, and 15B and the non-sensitive insulating layer 13, the sacrificial microlens and the non-photosensitive insulating layer are blanket etched (e.g., anisotropically etched, or etched back) nonselectively, at etch rate ratio of about 1:1 with respect to each other.

The microlenses 13R, 13G, and 13B can comprise a first microlens 13R, a second microlens 13G, and a third microlens 13B. The first microlens 13R may be formed in a position corresponding to the red color filter 11R, the second microlens 13G may be formed in a position corresponding to the red color filter 11G, and the third microlens 13B may be formed in a position corresponding to the blue color filter 11B.

With the method of fabricating an image sensor according to the exemplary embodiments as described above, the microlenses 13R, 13G, and 13B can comprise or be formed of a rigid material, as compared to the photosensitive material of the related art. Therefore, in a wafer back grinding process, a sawing process, and the like, the occurrence of particles adhering to the microlenses can be reduced or prevented. As a result, the sensitivity of the device as well as the fabricating yield thereof can be improved.

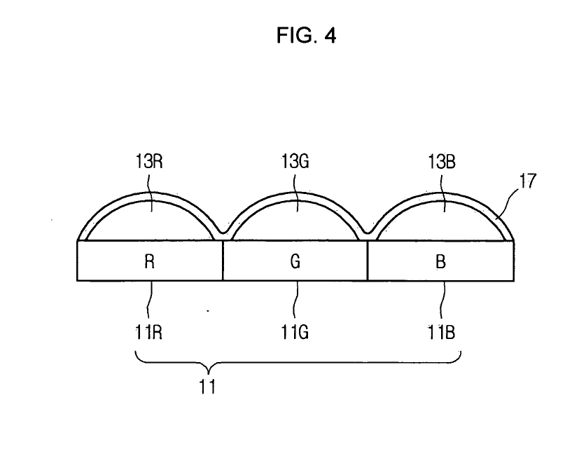

Meanwhile, as shown in FIG. 3, the microlenses 13R, 13G, 13B can have a gap therebetween. Alternatively, the exemplary method(s) of fabricating the image sensor according to various embodiments can further comprise forming a protective layer 17 on the microlenses 13R, 13G, and 13B, as shown in FIG. 4.

The protective layer 17 comprises or is formed of at least one of a low temperature oxide (LTO) layer or a spin on glass (SOG) layer. The LTO layer may comprise a tetraethyl orthosilicate (TEOS)-based glass or a plasma-silane (p-Si)-based glass. Of course, the material forming the protective layer 17 is not limited thereto, but it can be formed of various materials according to the design and demand.

In one embodiment, the protective layer 17 is gapless (e.g., there is no space between neighboring lenses in at least one location). The protective layer 17 results in formation of gapless microlenses and may prevent the microlenses 13R, 13G, and 13B from being damaged by external particles, etc.

The above description is based on the case where the microlenses are formed on the color filter layers. However, the present method of fabricating the image sensor is not limited thereto. As one example, a planarization layer can be formed on the color filter layer, and the microlens can then be formed on the planarization layer.

Meanwhile, the embodiments described with reference to FIGS. 1 to 4 are based on the case where the photosensitive layer for forming the sacrificial microlenses is formed on a non-photosensitive insulating film having a uniform thickness in a single sequence of steps.

However, the photosensitive layer for forming the sacrificial microlens is not necessarily deposited in a single step, but can be formed in multiple steps (e.g., two or three separate steps). Also, the thickness of the different photosensitive layers for forming the sacrificial microlenses can have different thicknesses according to their location.

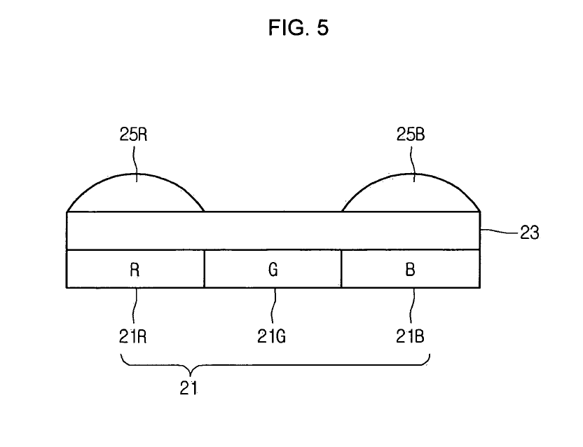

The case where the sacrificial microlenses are formed over two series of steps will now be described with reference to FIGS. 5 to 7. FIGS. 5 to 7 are views conceptually showing the method of fabricating the image sensor according to another embodiment.

With the method of fabricating an image sensor as shown in FIG. 5, the non-photosensitive insulating layer 23 is formed on the color filter layer 21. Prior to forming the color filter layer 21, the method can further comprise forming the light receiving unit in the semiconductor substrate. As one example, the light receiving unit can be a photodiode.

The color filter layer 21 can comprise a red color filter 21R, a green color filter 21G, and a blue color filter 21B. The arrangement of the red color filter 21R, the green color filter 21G, and the blue color filter 21B forming the color filter layer 21 can be varied according to the design. The red color filter 21R, green color filter 21G, and blue color filter 21B may have the same thickness or different thicknesses. However, when the color filters 21R, 21G, and 21B have different thicknesses, microlenses 25R, 25G, and 25B preferably have different thicknesses, such that the combined thicknesses of (1) color filter 21R and microlens 25R, (2) color filter 21G and microlens 25G, and (3) color filter 21B and microlens 25B are substantially equal.

The non-photosensitive insulating layer 23 can comprise or be formed of a rigid material and/or a transparent material as compared to the photosensitive material. The non-photosensitive insulating layer 23 can comprise or consist essentially of a transparent oxide layer as one example (see the discussion above).

Thereafter, the first sacrificial microlenses 25R and 25B are formed on the non-photosensitive insulating film 23 by essentially the same process as sacrificial microlenses 15R, 15G and 15B above. FIG. 5 shows the case where the sacrificial microlens 25R corresponding to the red color filter 21R and the sacrificial microlens 25B corresponding to the blue color filter 21B are formed first. However, the constitution of the first sacrificial microlens can be varied according to the design and demand.

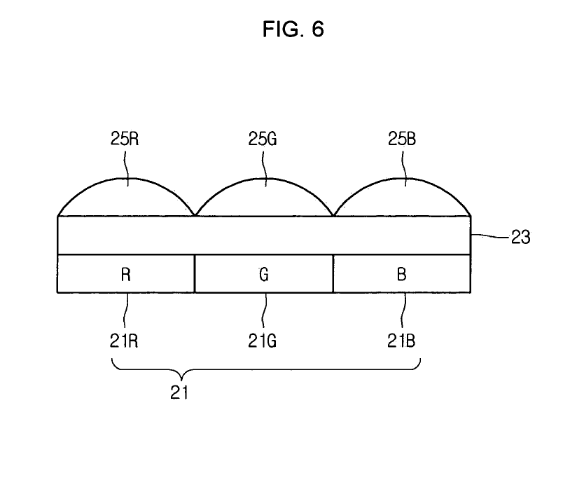

Next, as shown in FIG. 6, the second sacrificial microlens 25G is formed in the open spaces on the non-photosensitive insulating film 23. At this time, the thickness of the second sacrificial microlens 25G can be thicker than that of the first sacrificial microlenses 25R and 25B. Of course, the thickness of the second sacrificial microlens can be thinner than that of the first sacrificial microlens.

To avoid affecting the first sacrificial microlenses 25R and 25B, the material for the second sacrificial microlens 25G may be complementary to the material for the first sacrificial microlenses 25R and 25B. For example, the material for the first sacrificial microlenses 25R and 25B may be a positive photoresist, and the material for the second sacrificial microlens 25G may be a negative photoresist, or vice versa. Alternatively, the second sacrificial microlens 25G may be formed from the same type of photoresist by shifting the mask for the first sacrificial microlenses 25R and 25B by one unit pixel after formation of first sacrificial microlenses 25R and 25B.

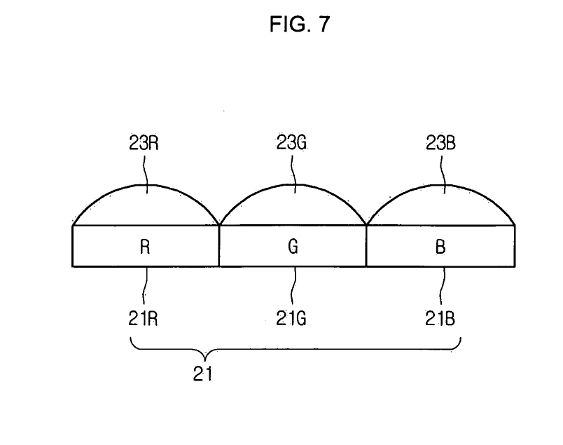

Thereafter, as shown in FIG. 7, the microlenses 23R, 23G, and 23B are formed from (or in) the non-photosensitive insulting layer by etching the sacrificial microlenses 25R, 25G, and 25B and the non-sensitive insulating layer 23 as described above with regard to FIG. 3. At this time, the sacrificial microlenses 25R, 25G, and 25B and the non-sensitive insulating layer 23 can be blanket etched at etch ratio of about 1:1.

With the method of fabricating the image sensor as described above, the microlenses 23R, 23G, and 23B can comprise or be formed of a rigid material, as compared to the photosensitive material. Therefore, in a wafer back grinding process, a wafer sawing process, and the like, the phenomenon that the particles such as polymer, silicon, etc., adhere to the microlenses can be reduced or prevented. As a result, the sensitivity of the device as well as the fabricating yield thereof can be improved according to the embodiment.

And, as shown in FIG. 5 to 7, when forming a first plurality of the sacrificial microlenses in one process and a second plurality of the sacrificial microlenses in another process, microlenses (or an array thereof) can be gapless (e.g., no gap between the neighboring lenses).

With the fabricating method of the image sensor as described herein, the method can further comprise forming a protective layer on the microlenses 23R, 23G, and 23B, similar to the process shown in FIG. 4.

Also, with the present method of fabricating the microlens array, a first plurality of the sacrificial microlenses can be formed first (e.g., the sacrificial microlenses corresponding to a first color in the color filter layer), and a second plurality of the sacrificial microlenses can be formed thereafter (e.g., the sacrificial microlenses corresponding to a second color in the color filter layer). The sacrificial microlenses corresponding to a third color in the color filter layer can be formed at the same time as the first or the second plurality of sacrificial microlenses, or it can be formed in a third sacrificial microlens-forming process. This latter embodiment is particularly advantageous when each color filter (e.g., R, G or B) in the color filter layer has a different thickness. At this time, the respective sacrificial microlenses can have the same thickness or a different thickness from each other.

The image sensor and the fabrication method thereof according to various embodiments have advantages including enabling an improvement in the sensitivity of the device as well as the fabricating yield thereof.

Any reference in this specification to “one embodiment”, “an embodiment”, “example embodiment” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a color filter layer on a semiconductor substrate; and
a microlens array on the color filter layer and comprising a non-photosensitive insulating layer, the microlens array comprising a first plurality of microlenses on a first color filter in the color filter layer, and a second plurality of microlenses on a second color filter in the color filter layer, the first and second pluralities of microlenses having different thicknesses from each other.

2. The image sensor according to claim 1, further comprising a planarization layer on the color filter layer.

3. The image sensor according to claim 1, further comprising a protective layer on the microlenses.

4. The image sensor according to claim 3, wherein the protective layer comprises at least one of a low temperature oxide (LTO) layer and a spin on glass (SOG) layer.

5. The image sensor according to claim 1, wherein the first color filter is a green color filter, and the second color filter is at least one of a red color filter and a blue color filter.

6. An image sensor comprising:
a color filter layer on a semiconductor substrate; and
a microlens array on the color filter layer and comprising a non-photosensitive insulating layer, the microlens array comprising a first microlens on a red color filter in the color filter layer, a second microlens on a green color filter in the color filter layer, and a third microlens on a blue color filter in the color filter layer, wherein the first, second, and third microlenses have the same thickness or different thicknesses from each other.

7. The image sensor according to claim 6, further comprising a planarization layer on the color filter layer.

8. The image sensor according to claim 6, further comprising a protective layer on the microlenses.

9. The image sensor according to claim 8, wherein the protective layer comprises at least one of a low temperature oxide (LTO) layer and a spin on glass (SOG) layer.

10. A method of fabricating an image sensor comprising:
forming a non-photosensitive insulating layer on a color filter layer;
forming a photosensitive layer on the non-photosensitive insulating layer;
forming sacrificial microlenses by patterning the photosensitive layer;
forming a microlens array from or in the non-photosensitive insulating layer by etching the sacrificial microlenses and the non-photosensitive insulating layer.

11. The method according to claim 10, further comprising forming a planarization layer on the color filter layer.

12. The method according to claim 10, wherein the neighboring microlenses are gapless.

13. The method according to claim 10, wherein the sacrificial microlenses comprise a first plurality of sacrificial microlenses on a green color filter in the color filter layer and a second plurality of sacrificial microlenses on a red and/or blue color filter in the color filter layer, the first sacrificial microlenses and the second sacrificial microlenses having different thicknesses from each other.

14. The method according to claim 10, wherein the sacrificial microlenses comprise a first sacrificial microlens on a red color filter in the color filter layer, a second sacrificial microlens on a green color filter in the color filter layer, and a third sacrificial microlens on a blue color filter in the color filter layer, all of the first, second, and third sacrificial microlenses having the same thickness.

15. The method according to claim 10, wherein the sacrificial microlenses comprise a first microlens on a red color filter in the color filter layer, a second sacrificial microlens on a green color filter in the color filter layer, and a third sacrificial microlens on a blue color filter in the color filter layer, the first, second, and third sacrificial microlenses having different thicknesses from each other.

16. The method according to claim 10, further comprising forming a protective layer on the microlenses.

17. The method according to claim 16, wherein the protective layer comprises at least one of a low temperature oxide (LTO) layer and a spin on glass (SOG) layer.

18. The method according to claim 10, wherein the sacrificial microlenses and the non-photosensitive insulating layer are blanket etched at etch ratio of about 1:1.
